(19) United States
(12) Patent Application Publication
(10) Pub. No.: US 2013/0270614 A1
(43) Pub. Date: Oct. 17, 2013

(54) FORMATION OF A TRENCH SILICIDE

(71) Applicant: Hiroyuki Yamasaki, Mamaronek, NY (US)

(72) Inventor: Hiroyuki Yamasaki, Mamaronek, NY (US)

(73) Assignee: TOSHIBA AMERICA ELECTRONIC COMPONENTS, INC., Irvine, CA (US)

(21) Appl. No.: 13/448,513

(22) Filed: Apr. 17, 2012

(51) Int. Cl. H01L 29/78; H01L 21/28; H01L 21/336

(52) U.S. Cl. 257/288; 438/300; 438/586; 257/E29.255; 257/E21.409; 257/E21.19

(57) ABSTRACT

Systems and methods are presented for controlling formation of a silicide region. A selective etch layer is utilized to control formation of a trench opening, and further can be utilized to open up a trench to facilitate correct exposure of an active Si region to subsequently form a silicide. Issues regarding over-dimension, under-dimension, and misalignment of a trench are addressed. The selective etch material is chosen to facilitate control of the trench formation and also to enable removal of the selective etch layer without affecting any adjacent structures/material. The selective etch layer can be an oxide, for example aluminum oxide, Al₂O₃. The selective etch layer can be utilized to prevent formation of silicide in a channel beneath a raised source/drain.

### FIELD

Embodiments described herein relate generally to methods and structures for utilizing a selective etch layer to constrain formation of a trench silicide structure to prevent electrically deleterious effects in semiconductor devices.

### BACKGROUND

Silicon large-scale integrated circuits, among other device technologies, are applied ubiquitously throughout modern society to accommodate the needs for digital information and digital control. An integrated circuit may be composed of a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc., of resultant integrated circuits. However, as semiconductor devices and device features have become smaller, conventional fabrication techniques are being challenged in their ability to produce finely defined features.

A particular development in the range of semiconductor devices are field effect transistors (FETs) where metal oxide semiconductor field effect transistors (MOSFET or MOS) and complimentary metal oxide semiconductor (CMOS) can utilize both p-type and n-type (PMOS and NMOS) transistors in conjunction with a gate structure(s). During construction of such semiconductor devices conversion of an active silicon (Si) layer can occur to form a silicide, for example, forming a raised source/drain region. A silicide is a conducting thin film comprising metal and silicon (e.g., TiSi₂, CoSi₂, WSi₂, NiSi, PtSi, etc.) and offers benefit of high-temperature stability with metal-like resistivity (e.g., 15-30 μohm-cm resistivity).

In an aspect, silicides can be formed as part of a trench forming operation, where such silicides are known as trench silicides. However, for example, during the formation process the trenching operation may not be correctly undertaken with respect to other device structures (e.g., too wide, too narrow, misaligned, etc.) resulting in an extraneous region of silicide being formed, unwanted regions of silicide being formed, insufficient silicide being formed, etc., which can lead to degradation in performance of the semiconductor device. Hence, formation of a silicide region has to be carefully controlled to ensure that a desired volume/structure of silicide is formed.

Thus, while technologies facilitate further miniaturization of semiconductor related devices and components, issues regarding construction of the devices (e.g., gate formation, surface profiles, etc.) are still to be addressed.

### SUMMARY

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of this summary is to present some concepts related to some exemplary non-limiting embodiments in a simplified form as a prelude to the more detailed description of the various embodiments that follow.

The subject innovation presents various techniques relating to utilizing a selective etch layer to facilitate formation of a silicide region. A selective etch layer can be utilized to control removal of a volume of material, and the region(s) from which the material is removed, during a trench silicide process. Controlling the trench forming operation and the volume of silicide subsequently formed prevents regions of unwanted silicide and/or regions of unconverted Si, thereby the minimizing performance degradation of a semiconductor device.

The various exemplary, non-limiting embodiments presented herein, in effect, utilize a selective etch layer to facilitate (a) constraining a trench opening to only remove required material and (b) selectively remove portions of the selective etch layer to expose a required volume of active Si to subsequently form a silicide. In an embodiment, the selective etch layer can be utilized to prevent formation of silicide in a channel beneath a raised source/drain. Selection of material for the selective etch layer can be a function of both ability to act as an etch stop layer and enabling selective removal without affecting other structures adjacent to the selective etch layer. A suitable material to form the selective etch layer is an oxide, such as Al₂O₃.

Hence, by utilizing a selective etch layer to control the silicide formation process, issues relating to trench over-dimension, trench under-dimension, trench misalignment, etc., are addressed.

### BRIEF DESCRIPTION OF THE DRAWINGS

FIG. 1 illustrates an initial structure in the formation of an unwanted volume of silicide.

FIG. 2 illustrates a structure in the formation of an unwanted volume of silicide.

FIG. 3 illustrates a structure comprising an unwanted volume of silicide resulting in gate shorting/current leakage.

FIG. 4 is a block diagram illustrating a non-limiting, exemplary embodiment of an initial structure in the formation of a silicide region of required dimension.

FIG. 5 is a block diagram illustrating a non-limiting, exemplary embodiment in the formation of a silicide region of required dimension.

FIG. 6 is a block diagram illustrating a non-limiting, exemplary embodiment in the formation of a silicide region of required dimension.

FIG. 7 is a block diagram illustrating a non-limiting, exemplary embodiment in the formation of a silicide region of required dimension.

FIG. 8 illustrates a flow for forming a silicide region having required dimension in accordance with one or more embodiments of the subject innovation.

FIG. 9 illustrates an initial structure in the formation of an unwanted volume of silicide.

FIG. 10 illustrates a structure in the formation of an unwanted volume of silicide.

FIG. 11 illustrates a structure comprising an unwanted volume of silicide resulting in gate shorting/current leakage.

FIG. 12 is a block diagram illustrating a non-limiting, exemplary embodiment of an initial structure in the formation of a silicide region of required dimension.

FIG. 13 is a block diagram illustrating a non-limiting, exemplary embodiment in the formation of a silicide region of required dimension.

FIG. 14 is a block diagram illustrating a non-limiting, exemplary embodiment in the formation of a silicide region of required dimension.

FIG. 15 is a block diagram illustrating a non-limiting, exemplary embodiment in the formation of a silicide region of required dimension.

FIG. 16 illustrates a flow for forming a silicide region having required dimension in accordance with one or more embodiments of the subject innovation.

FIG. 17 illustrates an initial structure in the formation of an unwanted volume of silicide.

FIG. 18 illustrates a structure in the formation of an unwanted volume of silicide.

FIG. 19 illustrates a structure comprising an unwanted volume of silicide resulting in gate shorting/current leakage.

FIG. 20 is a block diagram illustrating a non-limiting, exemplary embodiment of an initial structure in the formation of a silicide region of required dimension.

FIG. 21 is a block diagram illustrating a non-limiting, exemplary embodiment in the formation of a silicide region of required dimension.

FIG. 22 is a block diagram illustrating a non-limiting, exemplary embodiment in the formation of a silicide region of required dimension.

FIG. 23 is a block diagram illustrating a non-limiting, exemplary embodiment in the formation of a silicide region of required dimension.

FIG. 24 is a block diagram illustrating a non-limiting, exemplary embodiment in the formation of a silicide region of required dimension.

FIG. 25 is a block diagram illustrating a non-limiting, exemplary embodiment in the formation of a silicide region of required dimension.

FIG. 26 is a block diagram illustrating a non-limiting, exemplary embodiment in the formation of a silicide region of required dimension.

FIG. 27 illustrates a flow for forming a silicide region having required dimension in accordance with one or more embodiments of the subject innovation.

### DETAILED DESCRIPTION

As described in the background, owing to increased scaling of semiconductor devices, while silicide(s) can offer desired combinations of high-temperature stability and metal-like resistivity, etc., the volume and location of formed silicide has to be controlled to prevent such deleterious effects as electrical shortage, current leakage, etc., between a silicide region(s) and adjacent/nearby structures, such as a gate, channel, etc., in a semiconductor device. Further, as part of a trench silicide process, extraneous silicide can be formed in an undesirable location, e.g., in a channel beneath a raised source/drain silicide region. The subject innovation presents various techniques relating to prevention of such deleterious effects. Silicide can be formed by a solid-state reaction between an active Si region and a metal (e.g., NiPt+Si→NiSi), for example, as a result of diffusion during an annealing operation a metal-silicon reaction takes place in the regions where the Si and the metal are in contact. A material for a selective etch layer is chosen based on ability to control trench formation and also to enable removal of the selective etch layer without affecting any adjacent structures/material. Of particular concern is the formation of a silicide as part of a trench silicide operation.

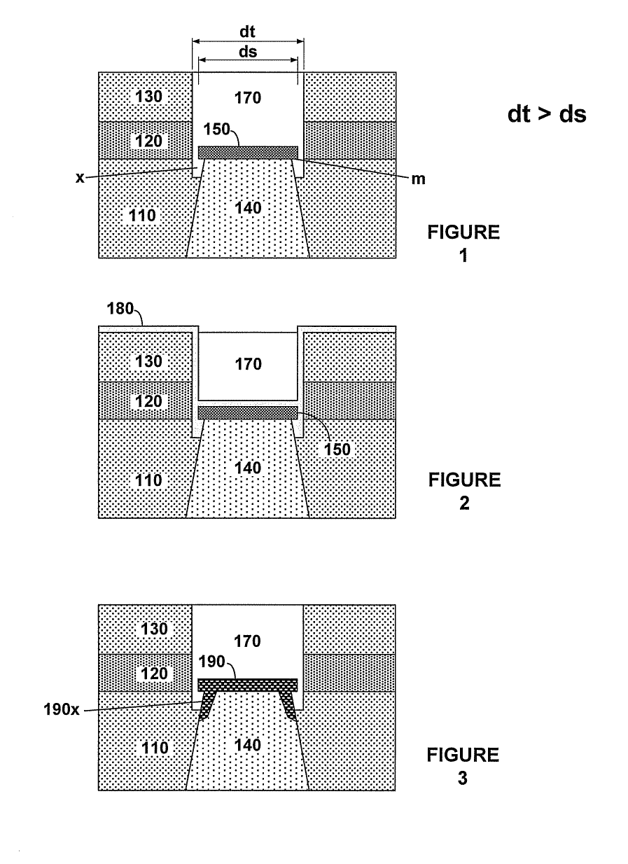

In the following description regarding FIGS. 1-3, 4-7, 9-11 and 12-15, the following elements can, in an aspect, be considered common: substrates 110, 210, 310, and 410, layers 120, 220, 320, and 420, layers 130, 230, 330, and 430, region 140, 240, 340, and 440, active Si region 150, 250, 350, and 450, layer 260 and 460, trench openings 170, 270, 370, and 470, and metal thin layer 180, 280, 380, and 480. However, it is to be appreciated that the sequence with which a respective structural element is formed, removed, the thickness of the formed structural element, etc., can vary from one process to another (e.g., respective processes presented in Figure sequences 1-3, 4-7, 9-11 and 12-15) as presented herein. Further, the material or operation to form and/or remove a respective structural element can vary from one process to another, as presented herein.

Silicide Formation with a Trench Having a Dimension Greater than an Active Si Region

FIGS. 1-3 and 4-7 illustrate respective trenching operations being performed where the trench width is greater than the width of an active Si region utilized to form the trench silicide. In FIGS. 1-3 the trench is formed in direct contact with the silicide. In FIGS. 4-7 a selective etch layer is utilized to constrain the extent of formation of the trench.

FIG. 1 illustrates an initial structure for subsequent processing for formation of a trench silicide. The initial structure of FIG. 1 comprises a substrate 110 (e.g., a substrate comprising Si, Si-compound, etc.), which, for example, can be patterned/doped, etc., to form initial regions of an nFET gate and a pFET gate (not shown). Depending upon the desired configuration of the semiconductor device various layers (e.g., layer 120, layer 130, etc.) can be deposited and/or formed on substrate 110. Layers 120 and 130 can comprise of any material as required in the formation of the semiconductor device, such as an insulator, dielectric, barrier layer, resist, protective layer, capping layer, etc. For example, layer 120 can be an insulator layer and layer 130 can be a resist which has been patterned (e.g., lithographed) with the required opening to form a trench. In another example, layer 120 can comprise an insulator, layer 130 is a dielectric which have been patterned in association with a pattern (not shown). It is to be appreciated that other layer combinations exist, and those presented here are for illustrative purposes only. In this particular example, a region of Si 140 exists beneath a region of active Si, active Si region 150, wherein active Si region 140 is formed for subsequent conversion to a silicide. However, Si region 140 can comprise material that is susceptible to silicide formation even though the silicide formation process may be focused on a different structure (e.g., active Si region 150). In an aspect, Si region can comprise a channel associated with a nFET gate of a pFET gate. Further, a trench 170 has been formed into the layers (e.g., substrate 110, layer 120, layer 130, etc.) exposing active Si region 150, whereby trench 170 can be subsequently filled with conductive material (e.g., metal) to form a via, contact, connector, etc. As shown in FIG. 1, the width dt of the trench opening 170 is greater (i.e., wider) than the width ds of the active Si region 150. Hence, rather than the walls of the trench 170 being aligned in accordance with the extremities of the active Si region 150, the magnitude of trench 170 is such that material in region x is removed from substrate 110, with an undercut m of the active Si region 150 occurring, thereby exposing Si region 140.

As illustrated in FIG. 2, a metal thin film is deposited to facilitate silicide formation. A metal thin film 180 is formed in trench 170, whereby region x is filled with the metal thin film 180. Hence, owing to the width dt of trench 170 being greater than width ds of the active Si region 150, metal thin film 180 is not only in contact with active Si region 150, but is also in contact with a portion of the underlying Si 140.

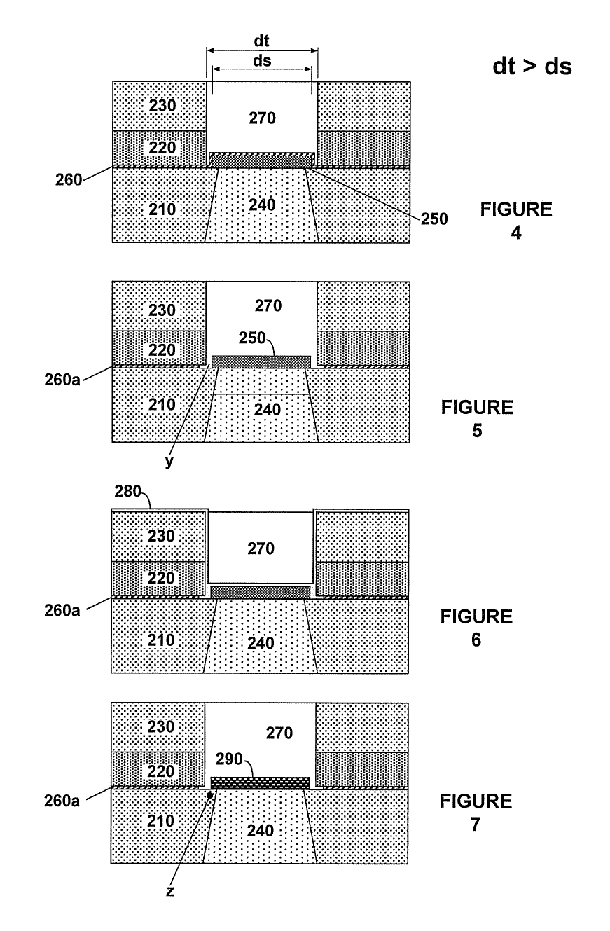

FIG. 3 illustrates a volume of formed silicide. Silicide can be formed by a solid-state reaction between Si (e.g., active Si region 150) and metal (e.g., metal thin film 180). Silicide is formed under an original surface (e.g., surface of active Si region 150 and surface of exposed Si (e.g., Si 140) in regions x and m. Hence, rather than just the active Si region 150 forming silicide 190, an underlaying portion of Si region 140 also forms silicide, silicide 190x. As previously mentioned, silicide is a conductor and while desired silicide is formed at silicide 190, unwanted silicide 190x is formed which can provide an electrical flow path between the silicide and a conductive region in the vicinity of silicide 190x. The electrical flowpath can give rise to deleterious effects such as electrical shortage/current leakage, etc., as well as affecting operation of a channel in association with a nFET gate or a pFET gate. Any metal comprising metal thin film 180 which remains unreacted (e.g., does not form silicide 190 or 190x) can be removed (e.g., by etching) to leave the silicide regions. Trench 170 can be subsequently filled with conductor to facilitate formation of a contact connecting with silicide 190/190x.

FIGS. 4-7 illustrate a series of exemplary, non-limiting embodiments to facilitate a trenching operation being performed where the trench width is greater than the width of the active Si region to form the trench silicide, and a selective etch layer is utilized to contain an amount of Si forming a silicide.

FIG. 4 illustrates an initial structure for subsequent processing for formation of a trench silicide. The initial structure of FIG. 4 comprises a substrate 210 (e.g., a substrate comprising Si, Si-compound, etc.), which, for example, can be patterned/doped, etc., to form initial regions of an nFET gate and a pFET gate, channel, etc. Depending upon the desired configuration of the semiconductor device various layers (e.g., layer 220, layer 230, etc.) can be deposited and/or formed on substrate 210. Layers 220 and 230 can comprise of any material as required in the formation of the semiconductor device, such as an insulator, dielectric, barrier layer, resist, capping layer, protective layer, etc. For example, layer 220 can be an insulator layer and layer 230 can be a resist which has been patterned (e.g., lithographed) with the required opening to form a trench. In another example, layer 220 can comprise an insulator, layer 230 is a dielectric which have been patterned in association with a pattern (not shown). It is to be appreciated that other layer combinations exist, and those presented here are for illustrative purposes only. A region of Si 240 is formed beneath a region of active Si, active Si region 250, wherein material comprising Si region 240 can be susceptible to silicide formation.

In comparison with FIGS. 1-3, FIGS. 4-7 include selective etch layer 260 formed over substrate 210 and active Si region 250. In an exemplary, non-limiting embodiment, selective etch layer 260 can act as an etch stop layer utilized to constrain the amount of Si forming silicide as described further below. In a further exemplary, non-limiting embodiment, selective etch layer 260 can comprise oxide (e.g., aluminum oxide, Al₂O₃, etc.) providing etch selectivity in comparison with material comprising layer 220 and layer 230.

Further, as illustrated in FIG. 4, a trench 270 has been formed into the layers (e.g., substrate 210, layer 220, layer 230, etc.). However, rather than trench 270 exposing active Si region 250 (as shown occurring in FIG. 1), selective etch layer 260 can act as an etch stop, thereby limiting material removal to material forming layer 220 and layer 230.

FIG. 5 illustrates a portion of selective etch layer 260 being removed (such that only selective etch layer 260a remains) thereby exposing active Si region 250. Owing to etch selectivity selective etch layer 260 is removed from region y while the surrounding Si regions (e.g., substrate 210) remain untouched.

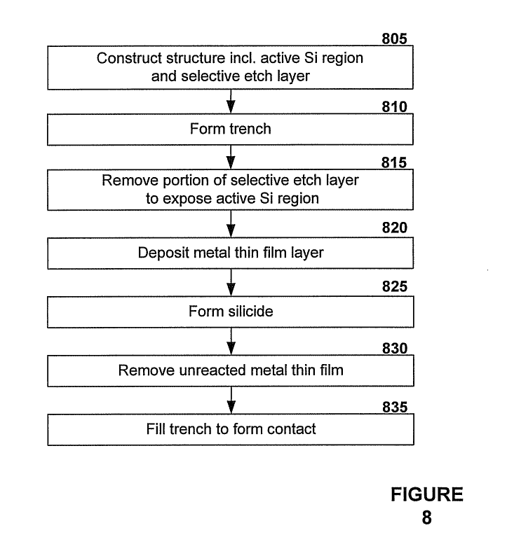

As shown in FIG. 6, a metal thin film is deposited to facilitate silicide formation. A metal thin film 280 is formed in trench 270, whereby region y is filled with the metal thin film 280. Hence, while the width dt of trench 270 is greater than width ds of active Si region 250, metal thin film 280 is only in contact with active Si region 250 and substrate 210, and no metal thin film 280 is in contact with Si region 240.

FIG. 7 illustrates formation of a desired volume of silicide. During the silicide forming operation, only silicide 290 is formed, with a portion z of substrate 210 separating metal thin film 280 from reacting with Si region 240. Hence, contrary to the process illustrated in FIGS. 1-3 and the formation of unwanted silicide, the exemplary, non-limiting embodiment of utilizing an selective etch layer (e.g., selective etch layer 260) to control formation of trench 270 results in silicide located only as desired, thereby minimizing deleterious effects such as electrical shortage/current leakage, etc.

FIG. 8 presents a flow diagram illustrating an exemplary, non-limiting embodiment to facilitate a trenching operation to form a trench silicide where the trench width is greater than the width of the active Si region to form the trench silicide, and a selective etch layer is utilized to contain an amount of Si forming the silicide.

As previously described, with reference to the various exemplary, non-limiting embodiments presented herein in FIGS. 4-7, a layer having different etching selectively to surrounding regions can act as (i) an etch stop layer and further (ii) constrain an amount of Si forming silicide as described further below. In an exemplary, non-limiting embodiment, the selective etch layer can comprise oxide (e.g., aluminum oxide, Al₂O₃, etc.) providing etch selectivity in comparison with surrounding material comprising dielectric, insulator, etc.

At 805, an initial structure is formed, whereby one or more structures are formed (e.g., a nFET gate, a pFET gate, and associated source/drain regions, channels, etc.) as part of a semiconductor component. A substrate (e.g., substrate 210) has a number of layers formed/deposited thereon (e.g., layer 220, layer 230, etc.) as required facilitate formation of the various features and regions comprising a semiconductor component. In an embodiment, a channel region (e.g., region 240) can have a region of active Si (e.g., active Si region 250) located above, which is to be subsequently converted to a silicide (e.g., silicide region 290). Over the active Si region a selective etch layer (e.g., layer 260) for controlling the extent of a trench opening is formed, above which are formed any other required layers (e.g., layer 220, layer 230, etc.).

At 810, a trench is formed to connect with the active Si region, wherein the trench can be formed by any suitable means, for example, etching. In an ideal situation the width and location of the trench (e.g., trench 270) would be perfectly sized and aligned with the active Si region. However, owing to processing conditions, the width of the trench can extend beyond a periphery of the active Si region resulting in unwanted removal of device material (e.g., FIG. 1, region x) which can further result in silicide being formed beyond that required (e.g., FIG. 3, region 190x). With the various embodiments presented herein, the selective etch layer can be utilized to constrain the formation of the trench and prevent unwanted removal of device material. By taking advantage of the etching selectivity of the selective etch layer in comparison with the etching susceptibility of other substrate regions (e.g., layers 220 and 230) material removal can be confined to those regions above the selective etch layer and any material beneath the selective etch layer (e.g., substrate 210, region 240, active Si layer 250, etc.) is protected from the trench forming operation.

At 815, selective etch layer is removed to expose the surface of the active Si region. Owing to the difference in etching susceptibilities between the selective etch layer and surrounding substrates/layers, selective etch layer can be removed without removal of any of the surrounding substrates/layers. In an embodiment, the selective etch layer can be removed by a wet etching operation. Unlike other etching operations (e.g., plasma etch, reactive ion etch (RIE), etc.) wet etching is isotropic in nature and thus portions of selective etch layer may be removed in conjunction with a portion of selective etch layer removed to expose the active Si region. Hence, selective etch layer can be removed from the vicinity of other structures (e.g., from region y, FIG. 5).

At 820, a metal thin film is deposited facilitating silicide formation. A metal thin film (e.g., metal thin film 280) is formed in the trench, and covers the active Si region, along with other surfaces comprising the trench and regions (e.g., region y). Owing to the selective etch layer acting as an etch stop layer, and its subsequent removal without affecting the surrounding regions (e.g., substrate 210, region 240, layer 220, etc.) no metal thin film is in contact with any region which may be susceptible to silicide formation (e.g., region 240).

At 825, a silicide forming operation is performed. Metal comprising the metal thin layer combines with Si in the active Si region to form a silicide, (e.g., silicide 290). During the silicide forming operation, as described above, only the active Si region is in contact with the metal thin film, with substrate material (e.g., substrate 210) separating the silicide susceptible material (e.g., region 240). Hence, in comparison with the process illustrated in FIGS. 1-3 and the formation of unwanted silicide, the exemplary, non-limiting embodiment of utilizing an selective etch layer (e.g., layer 260) to control formation of a trench, and surface exposed thereby, results in silicide only formed in a desired region, thereby minimizing deleterious effects such as electrical shortage/current leakage, etc.

At 830, any metal comprising the metal thin film which remains unreacted (e.g., does not form silicide 290) can be removed (e.g., by etching) to leave the silicide regions.

At 835, the trench opening can be subsequently filled with conductor (e.g., Al, W, etc.) to facilitate formation of a contact connecting with the silicide to form the raised source/drain.

Silicide Formation with a Trench Having a Dimension Less than an Active Si Region

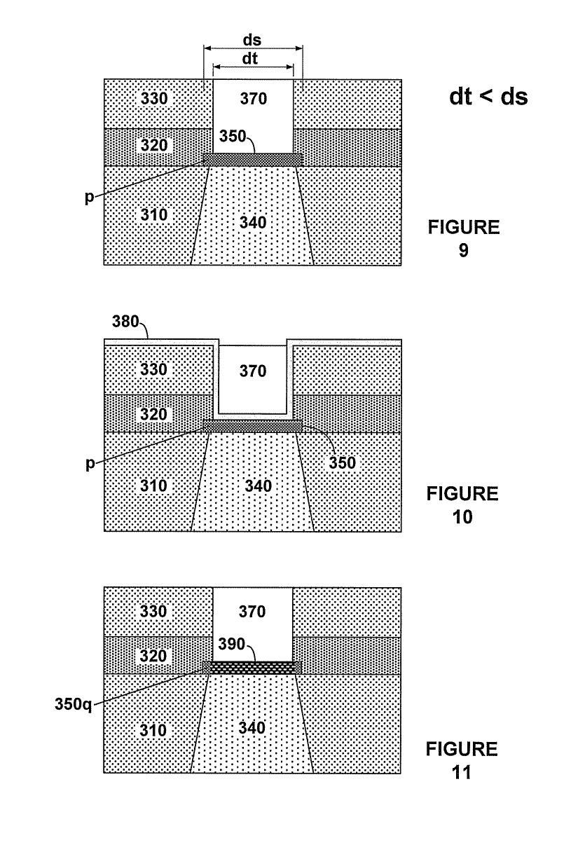

FIGS. 9-11 and 12-15 illustrate respective trenching operations being performed where the trench width is less than the width of an active Si region utilized to form the trench silicide. In FIGS. 9-11 the trench is formed to be in contact with the silicide. In FIGS. 12-15 a selective etch layer is utilized to extend the amount of active Si available to form silicide.

FIG. 9 illustrates an initial structure for subsequent processing for formation of a trench silicide. The initial structure of FIG. 9 comprises a substrate 310 (e.g., a substrate comprising Si, Si-compound, etc.), which, for example, can be patterned/doped, etc., to form initial regions of an nFET gate and a pFET gate (not shown). Depending upon the desired configuration of the semiconductor device various layers (e.g., layer 320, layer 330, etc.) can be deposited and/or formed on substrate 310. In this particular example, a region of Si 340 is formed beneath a region of active Si, active Si region 350, wherein Si region 340 is susceptible to silicide formation. Further, a trench 370 has been formed into the layers (e.g., layer 320 and layer 330, etc.) exposing active Si region 350, whereby trench 370 can be subsequently filled with conductive material (e.g., metal, etc.) to form a via, contact, connector, etc. As shown in FIG. 9, the width dt of the trench opening 370 is less (i.e., narrower) than the width ds of the active Si region 350. Hence, rather than the walls of the trench 370 being aligned in accordance with the extremities of the active Si region 350, the magnitude of trench 370 is such that region p remains unexposed by trench 370.

As illustrated in FIG. 10, a metal thin film is deposited to facilitate silicide formation. A metal thin film 380 is formed in trench 370. Owing to the width dt of trench 370 being less than width ds of the active Si region 350, metal thin film 380 is not in contact with portion p of active Si region 350.

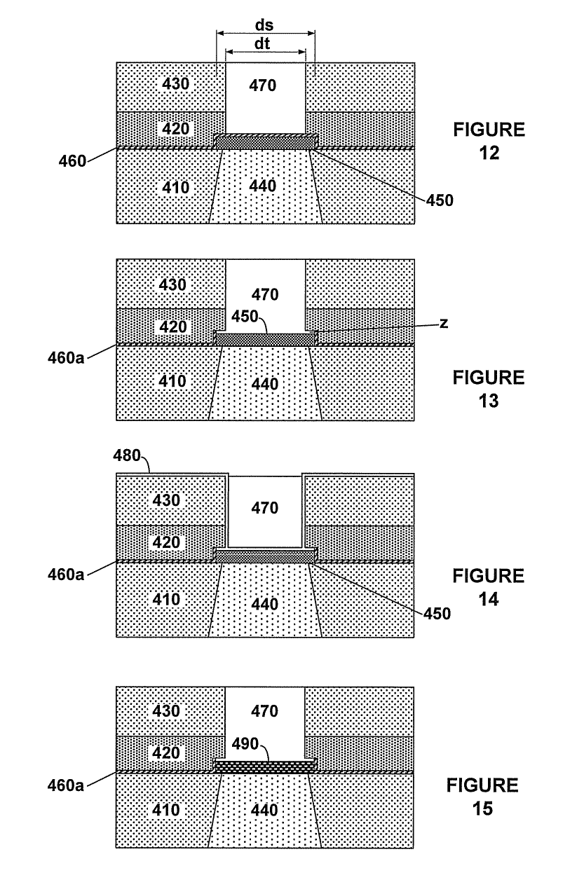

FIG. 11 illustrates a volume of formed silicide. Silicide can be formed by a solid-state reaction between Si (e.g., active Si region 350) and metal (e.g., metal thin film 380), for example as a result of diffusion during an annealing operation metal-silicon reaction takes place in the regions where the Si and the metal are in contact. However, rather than the entire volume of active silicon region 350 forming silicide 390, unconverted regions 350q of active Si region 350 remain. Hence, in a scenario where region 340 is a channel, the channel is not in contact with an expected volume of silicide but rather a combination of silicide (e.g., silcide 390) and active Si (e.g., active Si region 350q) which can give rise to performance degradation of the device.

FIGS. 12-15 illustrate a series of exemplary, non-limiting embodiments of a trenching operation being performed where the trench width is less than the width of the active Si region forming a trench silicide, with a selective etch layer being utilized to facilitate formation of the required volume of silicide.

FIG. 12 illustrates an initial structure for subsequent processing for formation of a trench silicide. The initial structure of FIG. 12 comprises a substrate 410 (e.g., a substrate comprising Si, Si-compound, etc.), which, for example, can be patterned/doped, etc., to form initial regions of an nFET gate and a pFET gate (not shown). Depending upon the desired configuration of the semiconductor device various layers (e.g., layer 420, layer 430, etc.) can be deposited and/or formed on substrate 410. In this particular example, a region of Si 440 resides beneath a region of active Si, active Si region 450, wherein in an embodiment, Si region 440 forms a channel associated with a nFET gate and/or a pFET gate, and Si region 440 is susceptible to silicide formation.

In comparison with FIGS. 9-11, FIGS. 12-15 include selective etch layer 460 formed over substrate 410 and active Si region 450. In an exemplary, non-limiting embodiment, selective etch layer 460 can act to extend the area of active Si exposed to form silicide, as described further below. In a further exemplary, non-limiting embodiment, selective etch layer 460 can be comprise an oxide (e.g., aluminum oxide, Al₂O₃, etc.) providing etch selectivity in comparison with material comprising layer 420 and layer 430.

Further, as illustrated in FIG. 12, a trench 470 has been formed into the layers (e.g., layer 420 and layer 430), exposing a portion of selective etch layer 460 residing above active Si layer 450.

FIG. 13 illustrates a portion of selective etch layer 460 being removed (such that only selective etch layer 460a remains) thereby exposing active Si region 450. Owing to etch selectivity a portion of selective etch layer 460 is removed from region z while the surrounding regions (e.g., layer 420) remains untouched. By utilizing etch selectivity, the entire surface of active Si layer 450 is exposed for further conversion to silicide.

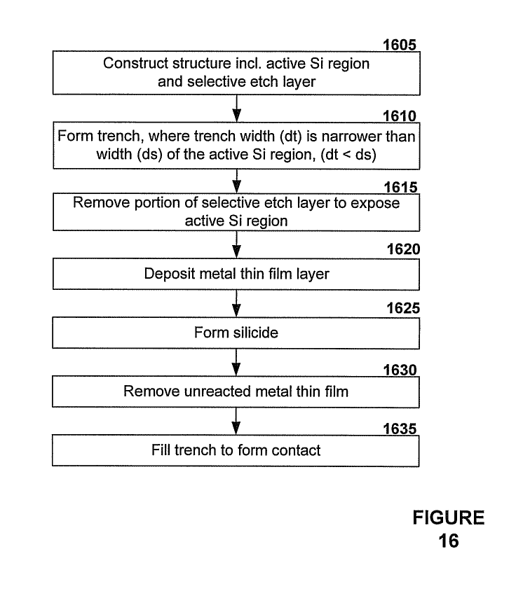

As shown in FIG. 14, a metal thin film is deposited to facilitate silicide formation. A metal thin film 480 is formed in trench 470 to cover active Si region 450, whereby region z is filled with metal thin film 480. Hence, while the width dt of trench 470 is narrower than width ds of active Si region 450, the amount of metal thin film 480 in contact with active Si region 450 is greater than that shown in FIG. 9.

FIG. 15 illustrates formation of a desired volume of silicide. During the silicide forming operation the entire active Si region 450 forms silicide. Hence, contrary to the process illustrated in FIGS. 9-11 where portions of active Si regions (e.g., active Si region 350q) remain which can negatively affect performance of the device, FIG. 15 illustrates an entire region of silicide 490 being formed from active Si region 450. Thus, in a scenario where region 440 is a channel, the channel is in contact with an expected volume of silicide (e.g., silicide 490) in accordance with the design specification of the device and hence, performance of the device is unaffected by portions of active Si regions remaining in contact with the channel.

FIG. 16 presents a flow diagram illustrating an exemplary, non-limiting embodiment of a trenching operation being performed where the trench width is less than the width of the active Si region to form a silicide, and a selective etch layer is utilized to maximise an amount of Si forming the silicide.

As previously described, the various exemplary, non-limiting embodiments presented herein in FIGS. 12-15, a selective etch layer having different etching selectively to surrounding regions can act as (i) an etch stop layer and further (ii) maximize an amount of Si available for forming silicide as described further below. In an exemplary, non-limiting embodiment, the selective etch layer can be comprise an oxide (e.g., aluminum oxide, Al₂O₃, etc.) providing etch selectivity in comparison with surrounding material comprising dielectric, etc.

At 1605, an initial structure is formed, whereby one or more structures are formed (e.g., a nFET gate, a pFET gate, associated source/drain, channel region, etc.) as part of a semiconductor component. A substrate (e.g., substrate 410) has a number of layers formed/deposited thereon (e.g., layer 420, layer 430, etc.) as required to facilitate formation of the various features and regions comprising a semiconductor component. In an embodiment, a channel (e.g., region 440) can have a region of active Si (e.g., active Si region 450) formed above, which is to be subsequently converted to a silicide (e.g., silicide region 490). Over the active Si region a selective etch layer (e.g., layer 460) is formed, above which are formed any other required layers (e.g., layer 420, layer 430, etc.).

At 1610, a trench is formed to connect with the active Si region, wherein the trench can be formed by any suitable means, for example, etching. In an ideal situation the width and location of the trench (e.g., trench 270) would be perfectly sized and aligned with the active Si region. However, owing to processing conditions, the width of the trench (dt) may be narrower than the edge of the active Si region (ds), hence dt<ds. If, during subsequent processing, the active Si region is not fully converted to silicide, a structure (e.g., a raised source/drain) comprising a combination of silicide (e.g., silicide 390) and active Si (e.g., active Si region 350q) can result which can give rise to performance degradation of the device (as shown in FIGS. 9-11). Hence, it is preferred that all of the material comprising the active Si region is converted to silicide. As described further, the removal of the selective etch layer increases the volume of active Si region exposed and thus maximizes the volume of silicide formed.

As 1615, selective etch layer is removed to expose the surface of the active Si region. Owing to the difference in etching susceptibilities between the selective etch layer and surrounding substrates/layers, selective etch layer can be removed without removal of any of the surrounding substrates/layers. In an embodiment, the selective etch layer can be removed by a wet etching operation. Unlike other etching operations (e.g., plasma etch, reactive ion etch (RIE), etc.) wet etching is isotropic in nature and thus portions of selective etch layer may be removed to expose the active Si region. Hence, selective etch layer can be removed from the vicinity of other structures (e.g., from region z, FIG. 13) thereby maximizing the area of active Si available for conversion to silicide.

At 1620, a metal thin film is deposited facilitating silicide formation. A metal thin film (e.g., metal thin film 480) is formed in the trench, and covers the active Si region, along with other surfaces comprising the trench and regions (e.g., FIG. 13, region z).

At 1625, a silicide forming operation is performed. Metal comprising the metal thin layer combines with Si in the active Si region to form a silicide, (e.g., silicide 490). During the silicide forming operation, as previously described, owing to the whole surface of the active Si region being exposed by the removal of the oxide layer, a region (e.g., region 490) completely formed from silicide is obtained thereby minimizing deleterious effects such as electrical shortage/current leakage, etc., compared with the partial silicide region (e.g., region 390) and remaining active Si (e.g., region 350q) resulting from the process depicted in FIGS. 9-11.

At 1630, any metal comprising the metal thin film which remains unreacted (e.g., does not form silicide 490) can be removed (e.g., by etching) to leave the silicide regions.

At 1635, the trench opening can be subsequently filled with conductor (e.g., Al, W, etc.) to facilitate formation of a contact connecting with the silicide forming a raised source/drain.

Silicide Formation with Misaligned Trench

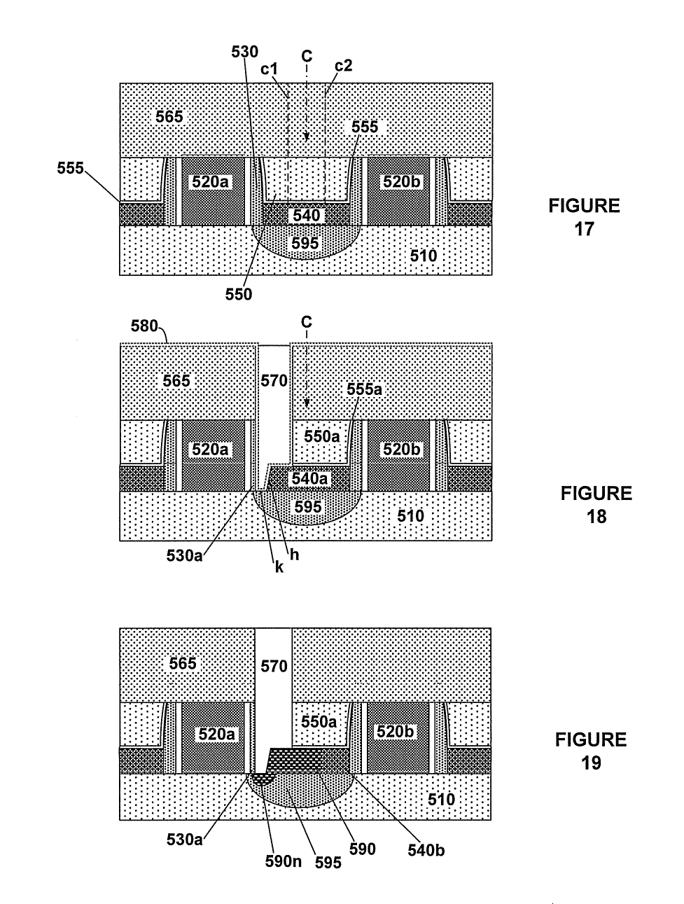

FIGS. 17-19 and 20-26 relate to the issue of a trench being misaligned during formation of a semiconductor device, resultant undesirable formation of a silicide (FIGS. 17-19) and how such formation can be prevented (FIGS. 20-26) by removal of a selective etch layer.

FIG. 17 illustrates an initial structure for subsequent processing for formation of a trench silicide. The initial structure of FIG. 17 comprises a substrate 510 (e.g., a substrate comprising Si, Si-compound, etc.) having associated FET gate structures 520a and 520b (wherein 520a and 520b can be any combination of nFET gate(s) and/or pFET gate(s)), wherein each gate comprise the various structures as is known in the art, including a spacer(s) 530. A raised source/drain 540 and insulator 550 separates FET gates 520a and 520b, with layer 555 (e.g., a protective layer) formed over the raised source/drain 540 and spacer(s) 530. A further layer 565 (e.g., any of an insulator layer, an interlayer dielectric, capping layer, resist layer, etc.) is formed over the FET gate regions. A channel region 595 is formed (e.g., by doping) beneath source/drain 540.

FIG. 18 illustrates a trench opening being formed in the semiconductor structure. Ideally, trench 570 would be formed centrally located between the FET gate structures 520a and 520b, about the central location axis C, as indicated by the broken lines c1 and c2 in FIG. 17. However, owing to misalignment, trench 570 is formed offset such that portions of 530, 540, 550 and 555 are removed to create portions 530a, 540a, 550a and 555a. Hence rather than the bottom of trench 570 exposing only the upper surface of source/drain 540, an end portion h of 540a is exposed along with a portion k of channel 595. The broken line indicates metal thin film 580 being subsequently formed in the trench opening 570 at portions h and k.

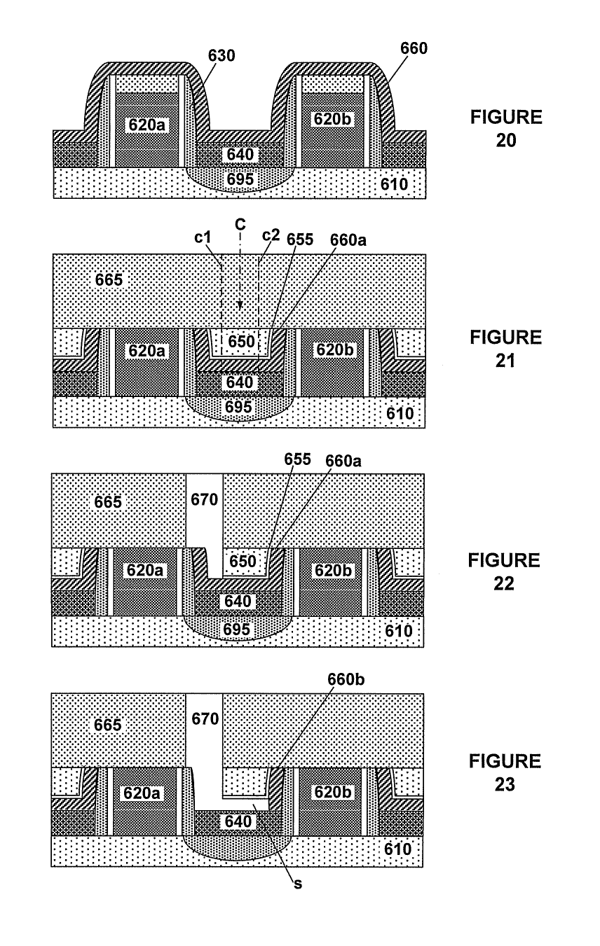

FIG. 19 illustrates a volume of formed silicide. Silicide 590 can be formed by a solid-state reaction between Si (e.g., active Si region 540a) and metal (e.g., metal thin film 580), for example as a result of diffusion during an annealing operation metal-silicon reaction takes place in the regions where the Si and the metal are in contact. Silicide 590 not only forms at active Si region 540a but also forms in the underlying substrate region 590n. Hence, in a device where a channel 595 is between the FET gate 520a and FET gate 520b, the unwanted silicide 590n can affect electron/hole flow, etc., in channel 595 thereby leading to performance degradation of the semiconductor device. Further, a portion of active Si region 540b remains unconverted to silicide, and the source/drain does not comprise an expected volume of silicide but rather a combination of silicide (e.g., silcide 590) and active Si (e.g., active Si region 540b) which can further negatively affect performance of the device.

FIG. 20 illustrates an initial structure for subsequent processing for formation of a trench silicide. The initial structure of FIG. 20 comprises a substrate 610 (e.g., a substrate comprising Si, Si-compound, etc.) having associated FET gate structures 620a and 620b (wherein 620a and 620b can be any combination of nFET gate(s) and/or pFET gate(s)), wherein each gate comprise the various structures as is known in the art, including a spacer(s) 630. A raised source/drain 640 region is positioned between FET gates 620a and 620b, over which is formed selective etch layer 660 which also acts a sacrificial layer taking advantage of etch selectivity, as previously described. A channel region 695 is formed (e.g., by doping) beneath source/drain 640.

FIG. 21 illustrates further processing with layers 650, 655, and 665 (e.g., any of an insulator layer, an interlayer dielectric, capping layer, resist layer, etc.) formed on the gates.

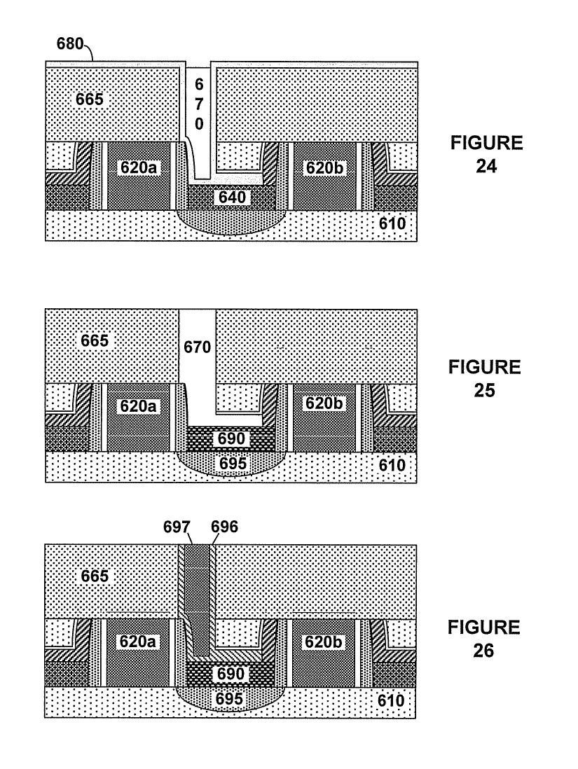

FIG. 22 depicts a trench opening 670 being formed in layers 665, 655 and 650. Ideally, trench 670 would be formed centrally located between the FET gate structures 620a and 620b, about the central location axis C, as indicated by the broken lines c1 and c2 in FIG. 21. However, owing to misalignment, trench 670 is formed offset. Owing to etch selectivity, while the etching process removes material from layers 665, 655, and 650, selective etch layer 660a acts as an etch stop layer. In an embodiment, layer 660a can be an oxide layer, e.g., Al₂O₃.

FIG. 23 illustrates a portion of selective etch layer 660a being removed to expose source/drain 640 underneath, where source/drain 640 comprises active Si for conversion to silicide. Based upon the etching conditions, e.g., etching period, a portion of selective etch layer 660a can remain as selective etch layer 660b, while region s is opened up.

FIG. 24 illustrates metal thin film 680 deposited in trench opening 670 and further filling region s.

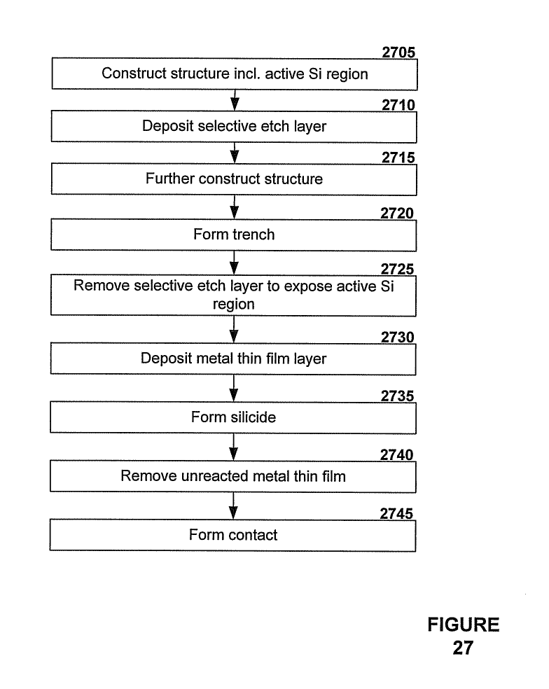

FIG. 25 illustrates conversion of the active Si material comprising source/drain 640 to form silicide 690. In comparison with the process depicted in FIGS. 17-19, silicide is only formed at the source/drain 690 and does not extend into the channel 695 to negatively affect performance of a device constructed with operations illustrated in FIGS. 17-19. As previously mentioned, any unreacted metal comprising metal thin film 680 which is not consumed in formation of silicide 690 can be removed.

FIG. 26 illustrates opening 670 being filled with liner 696 and conductor 697 (e.g., Al, W, etc.) to facilitate construction of a contact connecting with source/drain 690.

FIG. 27 presents a flow diagram illustrating an exemplary, non-limiting embodiment to facilitate a trenching operation where the trench is misaligned and a selective etch layer is utilized to constrain the effects of misalignment, thereby maximising an amount of Si forming a silicide without affecting a channel underlying a source/drain.

As previously described, the various exemplary, non-limiting embodiments presented herein in FIGS. 20-26, a selective etch layer having different etching selectively to surrounding regions can act as (i) an etch stop layer and further (ii) maximise an amount of Si for forming silicide by being selectively removed as described further below. In an exemplary, non-limiting embodiment, selective etch layer can be comprise an oxide (e.g., aluminum oxide, Al₂O₃, etc.) providing etch selectivity in comparison with surrounding material comprising substrate, dielectric, gate spacers, etc.

At 2705, an initial structure is formed, whereby one or more structures are formed (e.g., a nFET gate, a pFET gate, and associated source/drain regions) as part of a semiconductor component. A substrate (e.g., substrate 610) has gate regions formed thereon (e.g., FET gates 620a and 620b, sidewalls 630, etc.) with an active Si region (e.g., active Si region 640) formed between the gate regions, wherein the active Si region is to subsequently form a raised source/drain comprising a silicide.

At 2710, a selective etch layer is formed over the gate regions and the active Si region, wherein the selective etch layer is comprised of material to facilitate acting as an etch stop layer to a subsequently formed trench opening and, further, to be selectively removed to expose the underlying active Si region. As described above, the layer (e.g., layer 660) is chosen based upon its etch selectivity with regard to surrounding material layers (e.g., sidewall 630, active Si region 640, etc.). As previously mentioned, a suitable material to form the selective etch layer is an oxide such as Al₂O₃, but any material can be used which can function both as an etch stop as well as enabling selective removal without affecting other structures adjacent to the selective etch layer.

At 2715, the semiconductor device is further constructed with layers (e.g., layers 650, 655, and 665, comprising any of an insulator layer, an interlayer dielectric, capping layer, resist layer, barrier layer, etc.) formed on the gate regions and over the etch stop layer.

At 2720, a trench is formed to facilitate formation of a contact/connector with the active Si region, wherein the trench can be formed by any suitable means, for example, etching. In an ideal situation the width and location of the trench (e.g., trench 670) would be perfectly sized and aligned to be located between the gate structures as shown by centre axis C, and sidewalls c1 and c2 (indicated by broken lines) depicted in FIG. 21. However, owing to processing conditions, the trench opening is misaligned and thus removes portions of the structure (e.g., layers 655 and 650). However, unlike a structure which does not include a selective etch layer (e.g., as shown in FIG. 18) where the trench opening extends to, and removes portions of, the active Si region (e.g., active Si region 540) the selective etch layer prevents the trench from extending to expose the active Si region (e.g., active Si region 640). Hence, by utilizing the selective etch layer, the depth to which the trench opening is formed can be controlled.

At 2725, a portion of the selective etch layer (e.g., to form opening s, FIG. 23) is removed to facilitate exposure of the underlying active Si region (e.g., active Si region 640). Owing to the difference in etching susceptibilities between the selective etch layer and surrounding substrates/layers, the selective etch layer can be removed without removal of any of the surrounding substrates/layers. In an embodiment, the selective etch layer can be removed by a wet etching operation.

At 2730, a metal thin film is deposited facilitating silicide formation. A metal thin film (e.g., metal thin film 680) is formed in the trench, and covers the active Si region, along with other surfaces comprising the trench and regions (e.g., FIG. 23, region s).

At 2735, a silicide forming operation is performed. Metal comprising the metal thin layer combines with Si in the active Si region to form a silicide, (e.g., silicide 690). During the silicide forming operation, as previously described, owing to the whole surface of the active Si region being exposed by the removal of the selective etch layer, a region (e.g., region 690) completely comprising silicide is obtained thereby minimizing deleterious effects such as electrical shortage/current leakage, etc., compared with the partial silicide region (e.g., region 590 and active Si region 540b) resulting from the process depicted in FIGS. 17-19. Further, owing to the extent of the trench opening being controlled, and the subsequent removal of the selective etch layer only the active Si region is converted to silicide while the underlying material (e.g., channel 695) material remains intact and thus deleterious effects are avoided.

At 2740, any metal comprising the metal thin film which remains unreacted (e.g., does not form silicide 690) can be removed (e.g., by etching) to leave the silicide regions.

At 2745, a contact is formed in the opening connecting with the raised source/drain silicide. A barrier layer (e.g., layer 696) is formed on the inside of the opening and the remainder of the opening is filled with conductor (e.g., conductor 697, Al, W, etc.) to facilitate connection with the silicide forming the source/drain.

### General Considerations

Throughout the description, the term substrate is indicated to be the base layer upon which the various subsequent layers, nFET and pFET, resists, gate structures, channels, etc., are formed. The substrate can comprise of any suitable material, such as Si, Si-compound, etc., which can be subsequently doped to form respective nFET and pFET regions, etc.

The various layers comprising the various structures herein can be formed/deposited by any suitable process such as thermal, sputtering, a CVD process, for example, low pressure chemical vapor deposition (LPCVD), plasma enhanced chemical vapor deposition (PECVD), etc.

Any suitable technique can be used to pattern any of the material layers presented herein, (e.g., to form a nFET gate, a pFET gate, trench opening, etc.). For example, patterning can be created by employing a photoresist which is patterned using standard photolithographic techniques to form the required pattern to create the pattern, trenches, openings, etc., wherein the photoresist is exposed to electromagnetic radiation through a mask having an image pattern of a desired layout (e.g., desired trenches, openings, line patterning, etc.). Openings are then formed in the photoresist in order to form the desired layout, e.g., by etching away the exposed material (in the case of a positive photoresist) or etching away the unexposed material (in the case of a negative photoresist). Depending on the material of the photoresist, exposure can create a positive or a negative. With a positive photoresist, exposure causes a chemical change in the photoresist such that the portions of the photoresist layer exposed to light become soluble in a developer. With a negative photoresist, the chemical change induced by exposure renders the exposed portions of the photoresist layer insoluble to the developer. After exposure and develop, a layout according to the desired pattern is laid out on the first layer. A subsequent processing step, such as an etching step or an ion implantation step, can be performed and controlled according to the layout. For instance, after exposure and develop, material in the first layer not covered by the photoresist layer can be etched, thus transferring the pattern to the first layer. The photoresist can be subsequently removed. Etching can be by any viable dry or wet etching technique. For example, a wet or dry etching technique can be employed for patterning, while in another aspect, etching can be by a specific anisotropic etch.

Any etching/material removal technique is applicable to the various embodiments, as described herein. Wet etching can be utilized to remove a particular layer (e.g., any of layers 260, 460, 660, etc.) where a given layer may be susceptible to etch by a particular etchant while a neighboring layer is not (e.g., selective etching utilized to remove portion y of FIG. 5, portion z of FIG. 13, portion s of FIG. 23). In another example, anisotropic etching techniques can be utilized to control material removal in a specific direction (unlike standard wet etching) such as vertically down into a stack to form an opening (e.g., trenches 170, 270, 370, 470, 570, 670), etc.

Levelling of layers after formation can be by any suitable technique, e.g., by chemical mechanical polish/planarization (CMP) or other suitable process, to achieve a given dimension, in preparation for the next stage in creation of the replacement gate/contact structure, etc.

Stripping of a resist layer (e.g., where layers 130, 230, 330, 430, 565, 665 comprise a resist layer) involves the removal of unwanted resist from the semiconductor stack, while preventing removal of underlying layers and materials. Any suitable stripper can be utilized as required, such as organic stripper, inorganic stripper, dry stripping, etc.

It is to be appreciated that while the formation of gate structures, raised source/drain, channel regions, etc., are described, there may be certain procedures that are not fully disclosed during description of the various embodiments as presented herein. However, rather than provide description of each and every operation involved in the various operations facilitating formation, patterning, removal, etc., of each structure presented herein, for the sake of description only the general operations are described. Hence, while no mention may be presented regarding a particular operation pertaining to aspects of a particular figure, it is to be appreciated that any necessary operation, while either not fully disclosed, or not mentioned, to facilitate formation/deconstruction of a particular layer/element/aspect presented in a particular figure is considered to have been conducted. For example, while no mention may be made regarding a layer described in a preceding figure being leveled (e.g., by chemical mechanical polish, or other suitable operation) it is considered, for the sake of readability of the various exemplary embodiments presented herein, that the leveling process occurred, as have any other necessary operations. It is appreciated that the various operations, e.g., leveling, chemical mechanical polish, patterning, photolithography, deposition, layer formation, etching, etc., are well known procedures and are not necessarily expanded upon throughout this description.

The claimed subject matter has been described with reference to the drawings, wherein like reference numerals are used to refer to like elements throughout. In the description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

It is to be appreciated that the various Figures illustrating the various embodiments presented herein are simply rendered to facilitate understanding of the various embodiments. Accordingly, the various embodiments can be applicable to respective elements of any dimension, scaling, area, volume, distance, etc., and while a Figure may illustrate a dimension of one element rendered in association with another element, the respective dimensions, scaling, ratios, etc., are not limited to those as rendered but can be of any applicable magnitude.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim. The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. A semiconductor device comprising:
a silicon region formed in a substrate;
a silicide region formed on the silicon region;
a selective etch layer formed on the substrate;
a device layer formed on the substrate via the selective etch layer; and
a trench formed in the device layer and reaching to the silicide layer,
wherein the silicide region is located in an opening of the selective etch layer, and a bottom of the trench has a recess in which an edge of the opening of the selective etch layer steps back from a sidewall of the trench in a plane surface parallel to a bonded surface of the silicon region and the silicide region.

22. The semiconductor device of claim 21, wherein the selective etch layer is an insulator.

23. The semiconductor device of claim 21, wherein the selective etch layer is Al₂0₃.

24. The semiconductor device of claim 21, wherein the silicon region has a source layer or a drain layer in the bonded surface of the silicon region and the silicide region.

25. The semiconductor device of claim 21, wherein a width of the trench is wider than a width of the silicide region, in a plane surface parallel to the bonded surface of the silicon region and the silicide region.

26. The semiconductor device of claim 21, wherein a width of the trench is narrower than a width of the silicide region, in a plane surface parallel to the bonded surface of the silicon region and the silicide region.

27. The semiconductor device of claim 21, wherein the trench is formed between a first FET gate and a second FET gate, and the silicon region and the silicide region is located between the first FET gate and the second FET gate.

28. The semiconductor device of claim 21, wherein the silicide region is formed above a channel region of at least one of the first FET gate and the second FET gate.

29. A method for forming a semiconductor device, comprising:
forming a silicon region in a substrate;
selective forming an active silicon region on the silicon region;
forming a device layer on the substrate via a selective etch layer;
forming a trench in the device layer to reach to the selective etch layer;
etching the selective etch layer and exposing the active silicon region in bottom of the trench, and forming a recess in a bottom of the trench by retreating an edge of the opening of the selective etch layer from a sidewall of the trench;
forming a metal thin film on a side-surface of the trench, the recess, and the active silicon region;
fully converting the active silicon region to a silicide region by reacting the metal thin film and the active silicon region; and
removing the metal thin film.

30. The method of claim 29, wherein the metal thin film is formed by chemical vapor deposition (CVD).

31. The method of claim 29, wherein the selective etch layer is an insulator.

32. The method of claim 29, wherein the selective etch layer is Al₂0₃.

33. The method of claim 29, wherein the silicon region has a source region and a drain region in a bonded surface of the silicon region and the silicide region.

34. The method of claim 29, wherein a width of the trench is wider than a width of the silicide region, in a plane surface parallel to a bonded surface of the silicon region and the silicide region.

35. The method of claim 29, wherein a width of the trench is narrower than a width of the silicide region, in a plane surface parallel to a bonded surface of the silicon region and the silicide region.

36. The method of claim 29, wherein the trench is formed between a first FET gate and a second FET gate, and the silicon region and the silicide region is located between the first FET gate and the second FET gate.

37. The method of claim 29, wherein the silicide region is formed above a channel region of at least one of the first FET gate and the second FET gate.
